(19) United States
(12) Patent Application Publication
(10) Pub. No.: US 2023/0162951 A1
(43) Pub. Date: May 25, 2023

(54) APPARATUS AND METHOD OF MANUFACTURING DISPLAY DEVICE

(71) Applicants: Samsung Display Co., Ltd., Yongin-si (KR); WONIK IPS Co., Ltd., Pyeongtaek-si (KR)

(72) Inventors: Daesoo KIM, Yongin-si (KR); Kyungbok KIM, Yongin-si (KR); Sanggab KIM, Yongin-si (KR); Juhee LEE, Yongin-si (KR); Daewon CHOI, Yongin-si (KR); Daeil KIM, Pyeongtaek-si (KR); Jaekeun KIM, Pyeongtaek-si (KR); Kwangjong YOO, Pyeongtaek-si (KR); Changnam CHOI, Pyeongtaek-si (KR); Hyunku PARK, Yongin-si (KR); Yunjong YEO, Yongin-si (KR)

(73) Assignees: Samsung Display Co., Ltd., Yongin-si (KR); WONIK IPS Co., Ltd., Pyeongtaek-si (KR)

(21) Appl. No.: 17/992,421

(22) Filed: Nov. 22, 2022

(30) Foreign Application Priority Data
Nov. 22, 2021 (KR) 10-2021-0161758

(51) Int. Cl. H01J 37/32; H01L 27/12; H10K 71/00

(52) U.S. Cl. CPC H01J 37/32633; H01J 37/3244; H01J 37/32513; H01J 37/32522; H01J 37/32807; H01L 27/1259; H01L 51/56

(57) ABSTRACT

An apparatus and a method for manufacturing a display device are provided. The apparatus includes a plasma generator disposed outside a chamber, an adapter of the chamber, the adapter connecting the plasma generator to the chamber, a cooler connected to the adapter, an insulator connected to the cooler, and a diffuser connected to the insulator. A plasma generated by the plasma generator is supplied into the chamber through a flow path passing through the adapter, the cooler, the insulator, and the diffuser.

### CROSS-REFERENCE TO RELATED APPLICATION(S)

This application claims priority to and benefits of Korean Patent Application No. 10-2021-0161758 under 35 U.S.C. §119, filed on Nov. 22, 2021 in the Korean Intellectual Property Office (KIPO), the entire contents of which are incorporated herein by reference.

### BACKGROUND

### 1. Technical Field

Embodiments relate to an apparatus and a method of manufacturing a display device.

### 2. Description of the Related Art

Mobility-based electronic devices have a wide range of uses. In addition to small electronic devices such as mobile phones, tablet personal computers (PCs) have recently been widely used as mobile electronic devices.

A mobile electronic device may include a display device for providing visual information such as images or moving images to users in order to support various functions. As components for driving the display device have recently become smaller, a portion of the display device that occupies an electronic device has increased, and a structure of the display device that may be bent to have a certain angle from a flat state has been developed.

During manufacture of such a display device, various layers may be formed, and various processes may be used to form various layers. For example, at least one of the various layers of the display device may be formed through a process of patterning using a photoresist.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

In case that a photoresist is used, after disposing a photoresist forming a layer, etching may be performed along a pattern of the photoresist. Thereafter, post-processing may be performed to remove an etchant used for etching, and the photoresist may be removed. In order to perform the above process, a substrate may need to be moved to different locations, and in some cases, may need to be exposed to external air or pass through an area with many foreign materials. Foreign materials may settle on the substrate or a part of a layer may contact oxygen, thereby causing defects in a manufactured display device. One or more embodiments include an apparatus and method of manufacturing a display device capable of simplifying a process sequence and minimizing defects in manufacturing a display device by simultaneously performing post-processing with a photoresist removal process.

Additional aspects will be set forth in part in the description which follows and, in part, will be apparent from the description, or may be learned by practice of the presented embodiments of the disclosure.

According to one or more embodiments, an apparatus for manufacturing a display device may include a plasma generator disposed outside a chamber, an adapter of the chamber, the adapter connecting the plasma generator to the chamber, a cooler connected to the adapter, an insulator connected to the cooler, and a diffuser connected to the insulator. A plasma generated by the plasma generator may be supplied into the chamber through a flow path passing through the adapter, the cooler, the insulator, and the diffuser.

In an embodiment, the apparatus may further include a first coupler disposed on one of the adapter and the cooler, and a first accommodator disposed on another one of the adapter and the cooler, the first accommodator accommodating the first coupler.

In an embodiment, the apparatus may further include a second coupler disposed on one of the cooler or the insulator, and a second accommodator disposed on another one of the cooler or the insulator, the second accommodator accommodating the second coupler.

In an embodiment, the apparatus may further include a third coupler disposed on one of the insulator or the diffuser, and a third accommodator disposed on another one of the insulator or the diffuser, the third accommodator accommodating the third coupler.

In an embodiment, the apparatus may further include a nozzle head connected to the diffuser to inject the plasma into the chamber.

In an embodiment, an inner space of the diffuser may be connected to the flow path, and a cross-section of the flow path may be less than an inner cross-section of the diffuser.

In an embodiment, the apparatus may further include a susceptor on which a substrate may be seated.

In an embodiment, the apparatus may further include a water vapor supply connected to the plasma generator to supply water vapor to the plasma generator.

In an embodiment, the cooler may include a connection passing through the chamber and connected to the plasma generator.

In an embodiment, the apparatus may further include a sealing part between at least one of the adapter and the cooler and the plasma generator.

In an embodiment, at least two of the adapter, the cooler, the insulator, and the diffuser may contact each other.

According to one or more embodiments, a method of manufacturing a display device may include forming an electrode by disposing a photoresist on a substrate, disposing the substrate on a susceptor, supplying a gas to a plasma generator to convert the gas into a plasma, controlling occurrence of corrosion on a surface of the electrode by spraying the plasma to the substrate, and removing the photoresist by spraying the plasma to the substrate.

In an embodiment, the gas may include water vapor.

In an embodiment, the method may further include converting water into the water vapor and supplying the water vapor to the plasma generator.

In an embodiment, the method may further include guiding the gas or the plasma through a flow path that may be connected to the plasma generator and formed sequentially through an adapter, a cooler, an insulator, and a diffuser.

In an embodiment, the plasma generator may be connected to at least one of the adapter and the cooler.

In an embodiment, the method may further include spraying the plasma onto the substrate through a nozzle head connected to the diffuser.

In an embodiment, two of the adapter, the cooler, the insulator, and the diffuser may contact each other.

In an embodiment, the method may further include cooling a sealing part between the adapter and the plasma generator with the cooler.

In an embodiment, the controlling of the occurrence of corrosion on a surface of the electrode by spraying the plasma to the substrate, and the removing of the photoresist by spraying the plasma to the substrate may be performed in the same chamber.

Additional aspects will be set forth in part in the description which follows and, in part, will be apparent from the description, or may be learned by practice of the presented embodiments.

These general and specific embodiments may be implemented by using a system, a method, a computer program, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device, according to an embodiment;

FIG. 2 is an enlarged cross-sectional view schematically illustrating portion A shown in FIG. 1;

FIG. 3 is a cross-sectional view schematically illustrating a portion of an apparatus for manufacturing a display device, according to another embodiment;

FIG. 4 is a schematic plan view of a display device according to an embodiment;

FIG. 5 is a schematic cross-sectional view of the display device of FIG. 4 taken along line F-F′ in FIG. 4; and

FIGS. 6A to 6D are cross-sectional views schematically illustrating a method of manufacturing a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” Throughout the disclosure, the expression “at least one of a, b and c” indicates only a, only b, only c, both a and b, both a and c, both b and c, all of a, b, and c, or variations thereof.

It will be understood that although the terms “first,” “second,” etc. may be used herein to describe various components, these components should not be limited by these terms.

An expression used in the singular encompasses the expression of the plural, unless it has a clearly different meaning in the context.

It will be further understood that the terms “comprises”, “has”, “have”, and “includes”, and variations thereof (e.g., “comprising”), are used herein to specify the presence of stated features or elements, but do not preclude the presence or addition of one or more other features or elements.

It will be understood that when a layer, area, or element is referred to as being formed “on” another layer, area, or element, it can be directly or indirectly formed on the other layer, area, or element. For example, intervening layers, areas, or elements may be present.

Sizes of elements in the drawings may be exaggerated for convenience of explanation. In other words, since sizes and thicknesses of components in the drawings may be arbitrarily illustrated for convenience of explanation, the following embodiments are not limited thereto.

In the following embodiments, an x-axis, a y-axis, and a z-axis are not limited to three axes on an orthogonal coordinate system and may be broadly interpreted. For example, the x-axis, the y-axis, and the z-axis may be perpendicular to one another or may represent different directions that may not be perpendicular to one another.

When a certain embodiment may be implemented differently, a specific process order may be performed differently from the described order. For example, two consecutively described processes may be performed substantially at the same time or performed in an order opposite to the described order.

It will be understood that the terms “connected to” or “coupled to” may include a fluidic, physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

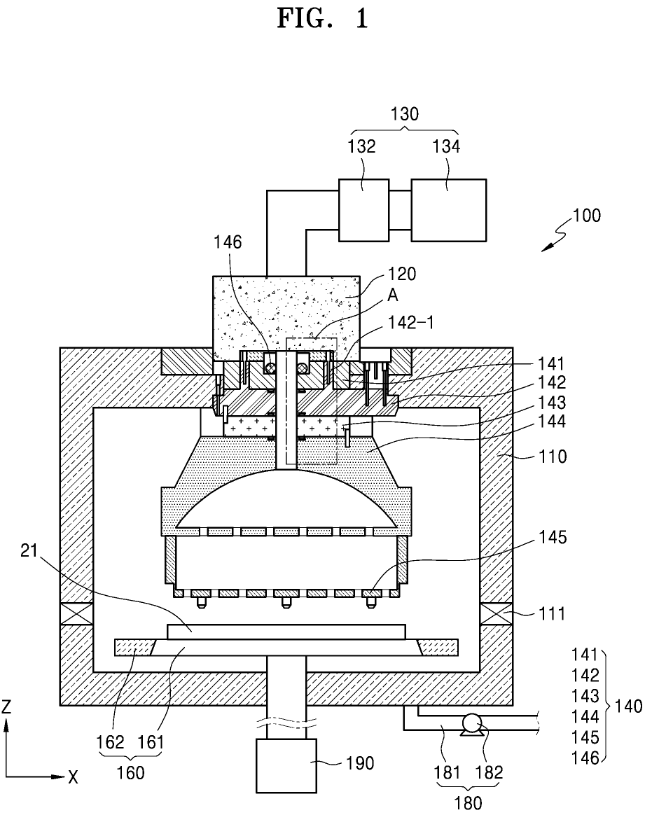

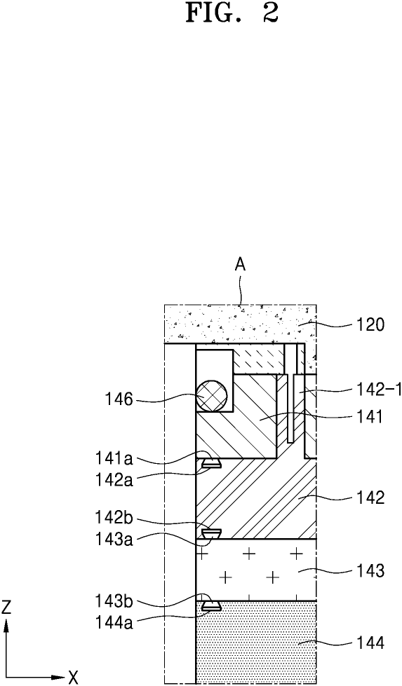

FIG. 1 is a schematic cross-sectional view of an apparatus for manufacturing a display device, according to an embodiment. FIG. 2 is an enlarged cross-sectional view schematically illustrating portion A shown in FIG. 1.

Referring to FIGS. 1 and 2, an apparatus 100 for manufacturing a display device may include a chamber 110, a plasma generator 120, a gas supply unit 130, a gas guide unit 140, a susceptor unit 160, a pressure-adjusting unit 180, and a driving unit 190.

The chamber 110 may include a space therein, and may have an opening connecting the inner space thereof to the outside. The opening may include an opening/closing portion 111 for opening and closing the opening. The opening/closing portion 111 may include a gate valve.

The plasma generator 120 may be disposed outside the chamber 110 and connected to the chamber 110. An electrode may be inside the plasma generator 120, and a gas flowing in from the outside of the chamber 110 may be converted into plasma. The plasma generator 120 may generate radicals by converting the gas into plasma.

The gas supply unit 130 may deliver the gas to the plasma generator 120. The gas supply unit 130 may include a storage unit 134 for storing a material for generating gas, and a vaporization unit 132 connected to the storage unit 134 to vaporize the material. The material stored in the storage unit 134 may be water, and the vaporization unit 132 may vaporize water to generate water vapor. The water vapor generated by the vaporization unit 132 may be supplied to the plasma generator 120. The storage unit 134 may store water and supply the water to the vaporization unit 132, or may be connected to the outside to temporarily store water supplied from the outside and supply the water to the vaporization unit 132.

The gas guide unit 140 may be connected to the plasma generator 120 to guide radicals generated by the plasma generator 120 into the chamber 110. A flow path through which radicals may move may be in the center of the gas guide unit 140. The flow path may be formed to pass through the gas guide unit 140.

The gas guide unit 140 may include an adapter 141, a cooling unit (cooler) 142, an insulator 143, a diffusion unit (diffuser) 144, a nozzle head 145, and a sealing unit (sealing part) 146.

The adapter 141 may be connected to the chamber 110 or disposed to be partially inserted into the chamber 110. The adapter 141 may be formed to be directly connected to the plasma generator 120. By connecting the plasma generator 120 to the chamber 110, the adapter 141 may prevent the position of the plasma generator 120 from being changed due to vibration or the like generated by the plasma generator 120.

The cooling unit 142 may be connected to the adapter 141. The cooling unit 142 may include a connection unit (connection) 142-1 that may be disposed to pass through the adapter 141 and connected to the plasma generator 120. Although not shown in the drawings, the cooling unit 142 may include a cooling path so that cooling water circulates therein. The cooling path may include a portion connected to the outside of the cooling unit 142 to introduce cooling water and a portion through which the cooling water may be discharged to the outside after circulating the cooling unit 142. Through this, by cooling the adapter 141 and at the same time cooling the sealing unit 146, damage to the sealing unit 146 may be reduced.

The insulator 143 may be connected to the cooling unit 142. The insulator 143 may insulate the cooling unit 142 and the diffusion unit 144 from each other. The insulator 143 may include an insulating material such as ceramic.

The diffusion unit 144 may be connected to the insulator 143 to diffuse radicals supplied through the flow path. The diffusion unit 144 may be formed so that an inner space of the diffusion unit 144 may expand toward a direction. For example, the inner space of the diffusion unit 144 may expand from the upper portion to the lower portion of the chamber 110. The inner surface of the diffusion unit 144 may be formed to be round, so that the flow of radicals may be made uniform in the inner space of the diffusion unit 144.

A separate baffle may be inside the diffusion unit 144. The baffle may be formed in a plate shape, and a hole through which radicals pass may be formed in the baffle. Multiple baffles may be provided, and the baffles may be arranged inside the diffusion unit 144 to be apart from each other.

The nozzle head 145 may be at an end of the diffusion unit 144. The nozzle head 145 may have injection holes formed to inject radicals to a substrate 21. The injection holes may be uniformly disposed in a front surface of the nozzle head 145.

The sealing unit 146 may be between the plasma generator 120 and the adapter 141 to prevent radicals or gas from being emitted from a portion where the plasma generator 120 and the adapter 141 may be connected to each other.

The adapter 141, the cooling unit 142, the insulator 143, and the diffusion unit 144 as described above may be integrally formed with each other or may be formed to be separate from each other. Hereinafter, for convenience of description, the adapter 141, the cooling unit 142, the insulator 143, and the diffusion unit 144 will be described in detail focusing on a case in which they may be formed to be separate from each other.

Two of the adapter 141, the cooling unit 142, the insulator 143, and the diffusion unit 144 that may be adjacent to each other may be in complete contact with each other. For example, the adapter 141 may be in complete contact with the cooling unit 142 on a surface, the cooling unit 142 may be in complete contact with the insulator 143 on a surface, and the insulator 143 may be in complete contact with the diffusion unit 144 on a surface.

The adapter 141, the cooling unit 142, the insulator 143, and the diffusion unit 144 may be coupled to each other through a coupling unit and an insertion unit.

For example, one of the adapter 141 and the cooling unit 142 may include a first coupling unit (first coupler) 141a, and the other of the adapter 141 and the cooling unit 142 may include a first insertion unit (first accommodator) 142a. The first coupling unit 141a may have a protrusion shape, and the first insertion unit 142a may have a groove shape. Hereinafter, for convenience of description, a case in which the adapter 141 includes the first coupling unit 141a and the cooling unit 142 includes the first insertion unit 142a will be described in detail.

The first coupling unit 141a as described above may be formed to protrude from the adapter 141. The first coupling unit 141a may be formed in a trapezoidal shape. The first coupling unit 141a may not deviate from the first insertion unit 142a by rotating the adapter 141 after being inserted into a separate groove formed in the first insertion unit 142a. As another embodiment, the first coupling unit 141a may be coupled to the first insertion unit 142a through a separate coupling member such as a screw or bolt after being inserted into the first insertion unit 142a. As another embodiment, the first coupling unit 141a and the first insertion unit 142a may be coupled to each other by being formed in a rectangular or square cross-sectional shape. The first coupling unit 141a and the first insertion unit 142a may be coupled to each other through a coupling member as described above.

One of the cooling unit 142 and the insulator 143 may include a second coupling unit (second coupler) 143a, and the other of the cooling unit 142 and the insulator 143 may include a second insertion unit (second accommodator) 142b. The second coupling unit 143a and the second insertion unit 142b may be respectively the same as or similar to the first coupling unit 141a and the first insertion unit 142a described above. Hereinafter, for convenience of description, a case in which the second coupling unit 143a may be on the insulator 143 and the second insertion unit 142b may be on the cooling unit 142 will be described in detail.

One of the insulator 143 and the diffusion unit 144 may include a third coupling unit (third coupler) 143b, and the other of the insulator 143 and the diffusion unit 144 may include a third insertion unit (third accommodator) 144a. The third coupling unit 143b and the third insertion unit 144a may be respectively the same as or similar to the first coupling unit 141a and the first insertion unit 142a described above. Hereinafter, for convenience of description, a case in which the third coupling unit 143b may be on the insulator 143 and the third insertion unit 144a may be on the diffusion unit 144 will be described in detail.

Two adjacent to each other from among the adapter 141, the cooling unit 142, the insulator 143, and the diffusion unit 144 through each coupling unit and insertion unit as described above may not only be in close contact with each other, but may not be separate from each other.

The susceptor unit 160 may support the substrate 21. The susceptor unit 160 may include a susceptor 161 on which the substrate 21 may be seated and a susceptor ring 162 around the susceptor 161. The susceptor ring 162 may be around the susceptor 161 and may include ceramic. The susceptor 161 may control the temperature of the substrate 21. For example, in the susceptor 161, a refrigerant such as cooling water may circulate therein.

The pressure-adjusting unit 180 may be connected to the chamber 110 to adjust the pressure inside the chamber 110. The pressure-adjusting unit 180 may include a pipe 181 connected to the chamber 110 and a pump 182 on the pipe 181.

The driving unit 190 may be connected to the susceptor unit 160 to elevate the susceptor unit 160. The driving unit 190 may include a cylinder. As another embodiment, the driving unit 190 may include a linear motor connected to the susceptor unit 160. As another embodiment, the driving unit 190 may include a ball screw connected to the susceptor unit 160 and a motor connected to the ball screw. As another embodiment, the driving unit 190 may include a rack gear connected to the susceptor unit 160, a gear connecting the rack gear, and a motor connected to the gear. The driving unit 190 is not limited to the above, and may include all devices and all structures connected to the susceptor 161 to linearly move the susceptor 161.

In terms of the operation of the apparatus 100 for manufacturing a display device, as described above, an electrode having a pattern may be formed on the substrate 21. A photoresist may be used, and a photoresist may be on the electrode.

The opening/closing portion 111 may be opened to insert the substrate 21 as described above into the chamber 110. The pressure-adjusting unit 180 may maintain the pressure inside the chamber 110 at atmospheric pressure, or to be the same as or similar to the internal pressure of a separate device connected to the chamber 110.

In case that the opening/closing portion 111 is opened, the substrate 21 may be inserted into the chamber 110 from the outside of the chamber 110 to be disposed on the susceptor 161. The substrate 21 may be transported in various ways. For example, the substrate 21 may be transported from the outside of the chamber 110 into the chamber 110 by a robot arm and seated on the susceptor 161. As another embodiment, the substrate 21 may be seated on a shuttle or the like, transported from the outside of the chamber 110 into the chamber 110, and seated on the susceptor 161. Hereinafter, for convenience of description, a case in which the substrate 21 may be supplied by a robot arm will be described in detail.

In case that the substrate 21 is seated on the susceptor 161, the opening/closing portion 111 may close an opening of the chamber 110, and the pressure-adjusting unit 180 may maintain the pressure inside the chamber 110 to be lower than atmospheric pressure.

The driving unit 190 may raise and lower the susceptor 161 to arrange the substrate 21 at a preset position so that the substrate 21 may be apart from the nozzle head 145 by a certain distance. Although not shown in the drawing, the operation of the driving unit 190 may be performed until the distance to the substrate 21, measured by a separate sensor, reaches a certain distance. As another embodiment, the driving unit 190 may be operated for a preset time.

In case that the substrate 21 is disposed at the preset position as described above, the gas supply unit 130 may supply a gas to the plasma generator 120, and the plasma generator 120 may convert the gas into a plasma to generate radicals. The generated radicals may be injected to the substrate 21 through the gas guide unit 140.

In case that the radicals are injected as described above, the surface of the electrode disposed on the substrate 21 may be treated. For example, chlorine groups (CI⁻) disposed on the surface of the electrode due to an etchant used to form a pattern of the electrode, may be effectively removed. Through this, the occurrence of corrosion on the electrode surface due to the chlorine groups on the surface of the electrode may be reduced.

During the above operation, the photoresist on the electrode surface may be removed due to the above radicals.

While the above operation may be in progress, the pressure-adjusting unit 180 may continuously discharge the gas inside the chamber 110 to the outside.

Accordingly, the apparatus 100 for manufacturing a display device may remove the photoresist as well as the chlorine groups on the electrode surface.

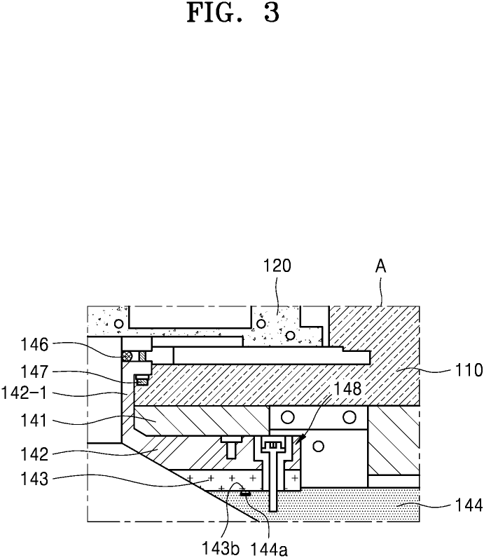

FIG. 3 is a cross-sectional view schematically illustrating a portion of an apparatus for manufacturing a display device, according to another embodiment.

Referring to FIG. 3, the apparatus 100 for manufacturing a display device may be similar to that illustrated in FIGS. 1 and 2. Hereinafter, for convenience of description, a detailed description will be given focusing on parts different from those of the apparatus 100 for manufacturing a display device illustrated in FIGS. 1 and 2.

The cooling unit 142 may include the connection unit 142-1 connected to the plasma generator 120. The connection unit 142-1 may be connected to the plasma generator 120 through a bolt or the like. The connection unit 142-1 may be formed to be partially bent.

The adapter 141 may be in the cooling unit 142, and may be disposed to be in close contact with the chamber 110 or to be inserted at least partially into the chamber 110. Although not shown in the drawing, the adapter 141 may be connected to the plasma generator 120 through a bolt or the like disposed to pass through the chamber 110.

At least one of the adapter 141, the cooling unit 142, the insulator 143, and the diffusion unit 144 may be formed to be separate from each other and may be connected through a bolt 147 or the like. Two adjacent to each other from among the adapter 141, the cooling unit 142, the insulator 143, and the diffusion unit 144 may be disposed to contact each other. Two adjacent to each other from among the adapter 141, the cooling unit 142, the insulator 143, and the diffusion unit 144 may include the coupling unit and the insertion unit described above.

For example, the diffusion unit 144 may include the third insertion unit 144a, and the insulator 143 may include the third coupling unit 143b. On the other hand, the adapter 141 may be connected to the diffusion unit 144 through a coupling member 148 such as a bolt disposed to pass through the cooling unit 142 and the insulator 143.

Accordingly, the apparatus 100 for manufacturing a display device may connect the gas guide unit 140 to the plasma generator 120 by connecting the cooling unit 142 to the plasma generator 120.

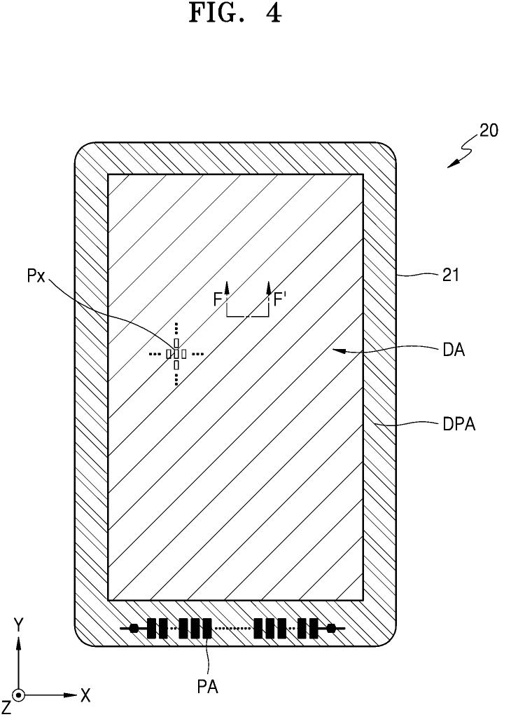

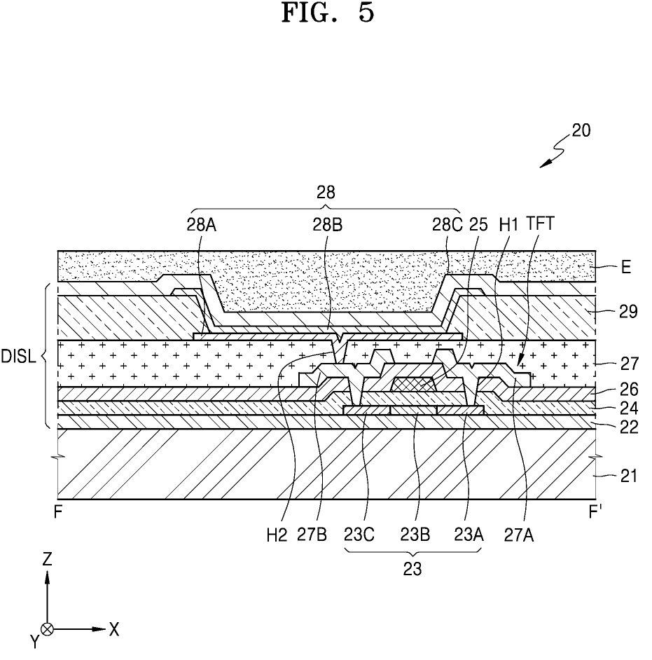

FIG. 4 is a schematic plan view of a display device according to an embodiment. FIG. 5 is a schematic cross-sectional view of the display device of FIG. 4 taken along line F-F′ in FIG. 4.

Referring to FIGS. 4 and 5, in a display device 20, a display area DA and a peripheral area DPA outside the display area DA may be defined on the substrate 21. A pixel Px may be in the display area DA, and a power wire (not shown) may be in the peripheral area DPA. Pixels Px may be provided in the display area DA. The pixels Px may be disposed to be apart from each other. Some of the pixels Px, others of the pixels Px, and the rest of the pixels Px may emit different colors. A pad unit PA may be in the peripheral area DPA.

The display device 20 may include a display layer DISL. A sealing member of the display layer DISL may include a sealing unit disposed on the substrate 21, and an encapsulation substrate (not shown) connected to the sealing unit and disposed to face the substrate 21. In another embodiment, the sealing member of the display layer DISL may include an encapsulation layer E for shielding at least a portion of the display layer DISL.

The display layer DISL as described above may include a thin-film transistor TFT and an organic light emitting device 28 on the substrate 21. The substrate 21 may be the same as or similar to that described above.

The thin-film transistor TFT may be formed on the substrate 21, a passivation layer 27 may be formed to cover the thin-film transistor TFT, and the organic light-emitting device 28 may be formed on the passivation layer 27.

A buffer layer 22 including an organic compound and/or an inorganic compound may further be formed on the substrate 21. For example, the buffer layer 22 may be formed of SiOₓ (x≥1) and/or SiNₓ (x≥1).

After an active layer 23 that may be arranged to have a certain pattern may be formed on the buffer layer 22, the active layer 23 may be covered by a gate-insulating layer 24. The active layer 23 may include a source area 23A and a drain area 23C, and further may include a channel area 23B therebetween.

The active layer 23 may include various materials. For example, the active layer 23 may include an inorganic semiconductor material such as amorphous silicon or crystalline silicon. As another example, the active layer 23 may include an oxide semiconductor. As another example, the active layer 23 may include an organic semiconductor material.

The source area 23A and the drain area 23C of the active layer 23 may be doped with impurities according to a type of the TFT such as a driving TFT (not shown) or a switching TFT (not shown).

A gate electrode 25 that corresponds to the active layer 23 and an interlayer insulating layer 26 that covers the gate electrode 25 may be formed on the gate-insulating layer 24.

After a contact hole H1 may be formed in the interlayer insulating layer 26 and the gate-insulating layer 24, a source electrode 27A and a drain electrode 27B may be formed on the interlayer insulating layer 26 to respectively contact the source area 23A and the drain area 23C.

The passivation layer 27 may be formed above the TFT, and a pixel electrode 28A of the organic light-emitting device 28 may be formed above the passivation layer 27. The pixel electrode 28A may be in contact with either the drain electrode 27B or the source electrode 27A of the TFT by a via hole H2 formed in the passivation layer 27. The passivation layer 27 may be formed of an inorganic material and/or an organic material to have a single-layer structure or a multi-layer structure. The passivation layer 27 may be formed as a planarization film having a flat top surface regardless of a curved shape of a lower film that may be disposed below the passivation layer 27 or may be curved along the curved shape of the lower film.

After the pixel electrode 28A may be formed on the passivation layer 27, a pixel-defining layer 29 may be formed of an organic material and/or an inorganic material to cover the pixel electrode 28A and the passivation layer 27, and may be opened so that the pixel electrode 28A may be exposed through an opening area of the pixel-defining layer 29.

The pixel electrode 28A may include a conductive oxide such as indium tin oxide (ITO), indium zinc oxide (IZO), zinc oxide (ZnO), indium oxide (In₂O₃), indium gallium oxide (IGO), aluminum zinc oxide (AZO), or a combination thereof. The pixel electrode 28A may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 28A may have a structure in which layers formed of ITO, IZO, ZnO, or In₂O₃ may be arranged above and below the reflective layer described above. The pixel electrode 28A may have a structure in which ITO/Ag/ITO may be stacked on each other.

An intermediate layer 28B and an opposite electrode 28C may be formed on the pixel electrode 28A. The opposite electrode 28C may be formed on the entire surface of the display area DA. The opposite electrode 28C may be formed on the intermediate layer 28B and the pixel-defining layer 29. Hereinafter, for convenience of description, a case where the opposite electrode 28C may be formed on the intermediate layer 28B and the pixel-defining layer 29 will be described in detail.

The pixel electrode 28A may function as an anode electrode, and the opposite electrode 28C may function as a cathode electrode. However, the polarity of the pixel electrode 28A may be switched with that of the opposite electrode 28C.

The pixel electrode 28A and the opposite electrode 28C may be insulated from each other by the intermediate layer 28B, and apply voltages having different polarities to the intermediate layer 28B such that an organic emission layer emits light.

The intermediate layer 28B may include an organic emission layer. As another example, the intermediate layer 28B may include an organic emission layer and may further include at least one of a first auxiliary layer including at least one of a hole injection layer and a hole transport layer, and a second auxiliary layer including at least one of an electron transport layer and an electron injection layer. However, embodiments are not limited thereto. The intermediate layer 28B may include an organic emission layer and may further include various functional layers (not shown).

Multiple intermediate layers 28B may be provided and form the display area DA. The intermediate layers 28B may be arranged to be apart from each other in the display area DA.

The opposite electrode 28C may include a conductive material having a low work function. For example, the opposite electrode 28C may include a (semi) transparent layer including at least one of Ag, Mg, Al, Pt, Pd, Au, Ni, Nd, Ir, Cr, lithium (Li), calcium (Ca), or an alloy thereof. In other embodiments, the opposite electrode 28C may further include a layer such as ITO, IZO, ZnO, and/or In₂O₃ on the (semi) transparent layer including the materials described above. The opposite electrode 28C may be integrally formed on the organic light emitting diodes in the display area DA.

An upper layer including an organic material may be formed on the opposite electrode 28C. The upper layer may be a layer provided to protect the opposite electrode 28C and to increase light extraction efficiency. The upper layer may include an organic material having a higher refractive index than that of the opposite electrode 28C. In other embodiments, the upper layer may be provided by stacking layers having different refractive indices. For example, the upper layer may be provided by stacking high refractive index layer/low refractive index layer/high refractive index layer. A refractive index of the high refractive index layer may be about 1.7 or more, and a refractive index of the low refractive index layer may be about 1.3 or less.

The upper layer may additionally include LiF. In other embodiments, the upper layer may additionally include an inorganic insulating material such as silicon oxide (SiO₂) and silicon nitride (SiNₓ). Such an upper layer may be omitted if necessary. However, hereinafter, for convenience of description, a case in which an upper layer may be on the opposite electrode 28C will be described in detail.

The encapsulation layer E for shielding the upper layer may cover a portion of the display area DA and the peripheral area DPA to prevent penetration of external moisture and oxygen. The encapsulation layer E may include at least one organic encapsulation layer and at least one inorganic encapsulation layer. Hereinafter, for convenience of description, a case in which the encapsulation layer E includes a first inorganic encapsulation layer, an organic encapsulation layer, and a second inorganic encapsulation layer sequentially stacked on the upper layer will be described in detail.

The first inorganic encapsulation layer may cover the opposite electrode 28C, and may include silicon oxide, silicon nitride, and/or silicon oxynitride. A shape of the first inorganic encapsulation layer may be formed along the shape of a structure therebelow, and thus, an upper surface of the first inorganic encapsulation layer may not be flat. The organic encapsulation layer may cover the first inorganic encapsulation layer, and unlike the first inorganic encapsulation layer, an upper surface of the organic encapsulation layer may be substantially flat. In more detail, the upper surface of the organic encapsulation layer may be substantially flat in a portion corresponding to the display area DA. The organic encapsulation layer may include at least one of polyethylene terephthalate, polyethylene naphthalate, polycarbonate, polyimide, polyethylene sulfonate, polyoxymethylene, polyarylate, and hexamethyldisiloxane. The second inorganic encapsulation layer covers the organic encapsulation layer, and may include silicon oxide, silicon nitride and/or silicon oxynitride.

A touch screen layer may be on the encapsulation layer E as described above.

An electrode may be formed by the apparatus for manufacturing a display device described with reference to FIG. 1 or FIG. 3. For example, the electrode may include at least one of the gate electrode 25, the source electrode 27A, the drain electrode 27B, the pixel electrode 28A, and the opposite electrode 28C. As another embodiment, in addition to the above electrodes, although not shown in the drawings, the electrode may be disposed between one of the source electrode 27A or the drain electrode 27B and the pixel electrode 28A to form a connection electrode connecting the pixel electrode 28A to one of the source electrode 27A and the drain electrode 27B using the apparatus for manufacturing a display device described with reference to FIGS. 1 or 3. As another embodiment, although not shown in the drawings, in case that various types of wires used in the display device 20 are formed, the apparatus for manufacturing a display device described with reference to FIG. 1 or FIG. 3 may be used. As another embodiment, in case that an electrode of the touch screen layer may be formed, the apparatus for manufacturing a display device described with reference to FIG. 1 or FIG. 3 may be used. However, hereinafter, for convenience of description, a case in which the source electrode 27A and the drain electrode 27B may be formed by the apparatus for manufacturing a display device described with reference to FIG. 1 or FIG. 3 will be described in detail.

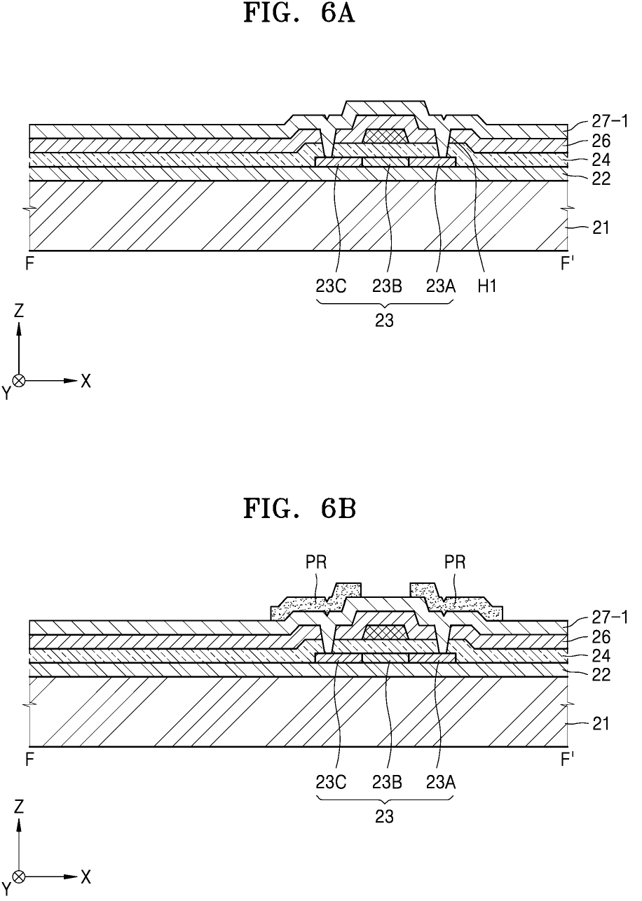

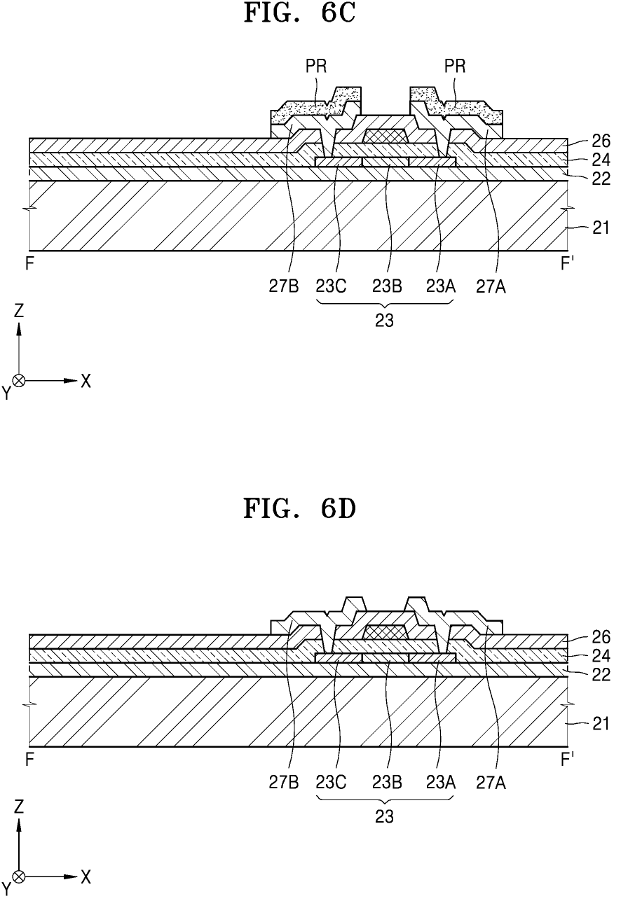

FIGS. 6A to 6D are cross-sectional views schematically illustrating a method of manufacturing a display device according to an embodiment.

Referring to FIG. 6A, the buffer layer 22, the active layer 23, the gate-insulating layer 24, the gate electrode 25, and the interlayer insulating layer 26 may be formed on the substrate 21. The contact hole H1 may be formed in the gate-insulating layer 24 and the interlayer insulating layer 26. Thereafter, an electrode layer 27-1 may be formed on the interlayer insulating layer 26. The electrode layer 27-1 may also be inside the contact hole H1.

Referring to FIG. 6B, a photoresist PR may be applied on the electrode layer 27-1 as described above. After the photoresist PR may be applied to the entire surface of the electrode layer 27-1, a certain area of the photoresist PR may be removed through a developing process to form a pattern. The photoresist PR may include a negative photoresist or a positive photoresist depending on a method of reacting to the light source.

Referring to FIG. 6C, a portion of the electrode layer 27-1 may be removed using an etchant in a state in which the photoresist PR having a pattern may be present. The etchant may remove the portion of the electrode layer 27-1 except for the area where the photoresist PR may be disposed.

In case that the above process is completed, the portions described above of the source electrode 27A and the drain electrode 27B may be disposed on the interlayer insulating layer 26.

Referring to FIG. 6D, the substrate 21, on which the above process has been completed, may be inside the apparatus for manufacturing a display device illustrated in FIG. 1 or FIG. 3. The removal of the portion of the electrode layer 27-1 by supplying an etchant to the substrate 21 may be performed in a separate apparatus than the apparatus for manufacturing a display device illustrated in FIG. 1 or FIG. 3.

As described above, after the substrate 21 may be disposed on a susceptor, water vapor may be supplied to a plasma generator by a gas supply unit to generate radicals and supply it to the substrate 21. The radicals may move along a gas guide unit, and after being diffused in a diffusion unit, the radicals may be sprayed onto one surface of the substrate 21 through a nozzle head.

In case that the radicals are sprayed as described above, the radicals may react with at least one of the photoresist, the etchant remaining in the source electrode 27A and the drain electrode 27B and ions of the etchant to remove the ions of the etchant and the etchant from the surfaces of the source electrode 27A and the drain electrode 27B.

The above process may be continued for a preset time. The radicals may remove the photoresist PR while removing at least one of the etchant and the ions of the etchant as described above or after removing at least one of the etchant and the ions of the etchant. As described above, the above operations may be performed simultaneously or sequentially in the same chamber, rather than while the substrate 21 may be in different spaces.

After the above process may be completed, the passivation layer 27, the pixel electrode 28A, the pixel-defining layer 29, the intermediate layer 28B, the opposite electrode 28C, and the encapsulation layer E may be disposed on the source electrode 27A and the drain electrode 27B to manufacture a display device.

Accordingly, the method of manufacturing a display device may reduce working time and increase working efficiency by removing the photoresist PR as well as removing at least one of the etchant and the ions of the etchant in the same chamber.

The method of manufacturing a display device does not require a separate device to perform each process by removing the photoresist as well as at least one of the etchant and the ions of the etchant in the same chamber, and may prevent oxidation of various layers on the substrate 21 due to exposing the substrate 21 to external air during each process.

An apparatus and method of manufacturing a display device according to embodiments may involve simplified processing. An apparatus and method of manufacturing a display device according to embodiments may minimize the degree of exposure of a substrate to external air in case that the substrate is moved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. An apparatus for manufacturing a display device, the apparatus comprising:
a plasma generator disposed outside a chamber;
an adapter of the chamber, the adapter connecting the plasma generator to the chamber;
a cooler connected to the adapter;
an insulator connected to the cooler; and
a diffuser connected to the insulator,
wherein a plasma generated by the plasma generator is supplied into the chamber through a flow path passing through the adapter, the cooler, the insulator, and the diffuser.

2. The apparatus of claim 1, further comprising:
a first coupler disposed on one of the adapter and the cooler; and
a first accommodator disposed on another one of the adapter and the cooler, the first accommodator accommodating the first coupler.

3. The apparatus of claim 1, further comprising:
a second coupler disposed on one of the cooler or the insulator; and
a second accommodator disposed on another one of the cooler or the insulator, the second accommodator accommodating the second coupler.

4. The apparatus of claim 1, further comprising:
a third coupler disposed on one of the insulator or the diffuser; and
a third accommodator disposed on another one of the insulator or the diffuser, the third accommodator accommodating the third coupler.

5. The apparatus of claim 1, further comprising:
a nozzle head connected to the diffuser to inject the plasma into the chamber.

6. The apparatus of claim 1, wherein
an inner space of the diffuser is connected to the flow path, and
a cross-section of the flow path is less than an inner cross-section of the diffuser.

7. The apparatus of claim 1, further comprising:
a susceptor on which a substrate is seated.

8. The apparatus of claim 1, further comprising:
a water vapor supply connected to the plasma generator to supply water vapor to the plasma generator.

9. The apparatus of claim 1, wherein the cooler comprises a connection passing through the chamber and connected to the plasma generator.

10. The apparatus of claim 1, further comprising:
a sealing part between at least one of the adapter and the cooler and the plasma generator.

11. The apparatus of claim 1, wherein at least two of the adapter, the cooler, the insulator, and the diffuser contact each other.

12. A method of manufacturing a display device, the method comprising:
forming an electrode by disposing a photoresist on a substrate;
disposing the substrate on a susceptor;
supplying a gas to a plasma generator to convert the gas into a plasma;
controlling occurrence of corrosion on a surface of the electrode by spraying the plasma to the substrate; and
removing the photoresist by spraying the plasma to the substrate.

13. The method of claim 12, wherein the gas includes water vapor.

14. The method of claim 13, further comprising:
converting water into the water vapor and supplying the water vapor to the plasma generator.

15. The method of claim 12, further comprising:
guiding the gas or the plasma through a flow path that is connected to the plasma generator and formed sequentially through an adapter, a cooler, an insulator, and a diffuser.

16. The method of claim 15, wherein the plasma generator is connected to at least one of the adapter and the cooler.

17. The method of claim 15, further comprising:
spraying the plasma onto the substrate through a nozzle head connected to the diffuser.

18. The method of claim 15, wherein two of the adapter, the cooler, the insulator, and the diffuser contact each other.

19. The method of claim 15, further comprising:
cooling a sealing part between the adapter and the plasma generator with the cooler.

20. The method of claim 15, wherein the controlling of the occurrence of corrosion on a surface of the electrode by spraying the plasma to the substrate, and the removing of the photoresist by spraying the plasma to the substrate are performed in a same chamber.
